(19) United States
(12) Patent Application Publication
(10) Pub. No.: US 2010/0149719 A1
(43) Pub. Date: Jun. 17, 2010

(54) Thermal device with ionized air flow

(76) Inventors: Johan F. Ploeg, Hillsboro, OR (US); Seri Lee, Durham, NC (US)

Correspondence Address: INTEL CORPORATION;c/o CPA Global, P.O. BOX 52050, MINNEAPOLIS, MN, 55402, US

(21) Appl. No.: 12/655,584

(22) Filed: Dec. 31, 2009

Related U.S. Application Data
(63) Continuation of application No. 11/967,854, filed on Dec. 31, 2007.

(51) Int. Cl. H05F 3/00; H05K 7/20

(52) U.S. Cl. 361/231; 361/694

(57) ABSTRACT

In some embodiments a thermal device such as a heat sink cools an electronic device. An electrokinetic airflow generating device uses a positively charged source and also uses at least a portion of the thermal device as a negatively charged or grounded probe to provide electrokinetically driven airflow. Other embodiments are described and claimed.

### TECHNICAL FIELD

The inventions generally relate to a thermal device with electrokinetic air flow.

### BACKGROUND

Increasing levels of component power and power density from electronic devices such as a Central Processing Unit (CPU) and a GMCH (Graphics and Memory Controller Hub) are creating an increased demand for air flow in thermal management solutions. This results in high acoustic noise levels in computer platforms. A need for a more efficient cooling with low acoustic noise level signatures exists in order to expand the thermal dissipation performance envelope for, in particular, consumer electronics products such as set-top boxes and high definition (HD) televisions (TVs).

### BRIEF DESCRIPTION OF THE DRAWINGS

The inventions will be understood more fully from the detailed description given below and from the accompanying drawings of some embodiments of the inventions which, however, should not be taken to limit the inventions to the specific embodiments described, but are for explanation and understanding only.

FIG. 1 illustrates a system according to some embodiments of the inventions.

FIG. 2 illustrates a system according to some embodiments of the inventions.

FIG. 3 illustrates a system according to some embodiments of the inventions.

FIG. 4 illustrates a system according to some embodiments of the inventions.

FIG. 5 illustrates a system according to some embodiments of the inventions.

FIG. 6 illustrates a system according to some embodiments of the inventions.

FIG. 7 illustrates a system according to some embodiments of the inventions.

FIG. 8 illustrates a system according to some embodiments of the inventions.

FIG. 9 illustrates a system according to some embodiments of the inventions.

FIG. 10 illustrates a system according to some embodiments of the inventions.

FIG. 11 illustrates a system according to some embodiments of the inventions.

### DETAILED DESCRIPTION

Some embodiments of the inventions relate to a thermal device with electrokinetic air flow.

In some embodiments a thermal device such as a heat sink cools an electronic device. An electrokinetic airflow generating device uses a positively charged source and also uses at least a portion of the thermal device as a negatively charged or grounded probe to provide electrokinetically driven airflow.

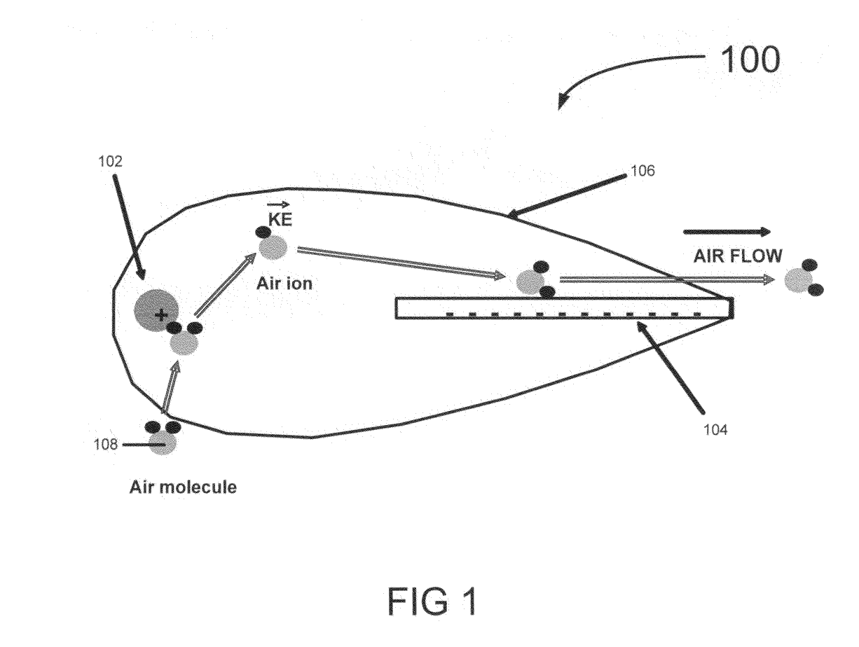

FIG. 1 illustrates a system 100 according to some embodiments. In some embodiments system 100 includes a positive charged source 102, a negative charged plate 104, and an electrostatic field 106. An air molecule 108 is ionized in the electrostatic field 106. The positively charged source 102 converts the air molecule into an air ion and the negatively charge plate converts the air ion back into an air molecule. In some embodiments, system 100 is a Forced-Air Noise-Less Electrokinetic System (FANLES). A FANLES system such as system 100 is implemented using all solid state with no moving parts, and is therefore virtually silent and very reliable. Using a FANLES, fan-less air movement can be achieved through air ionization and kinetic energy induction to ionized air molecules from the electrostatic field 106. The phenomenon schematically illustrated in FIG. 1 is known as the Electrokinetic effect

Technology using the Electrokinetic effect has been used previously in commercial devices to ionize and purify air. It has also been used to cool electronic devices and systems. However, in some embodiments a heat sink is combined with an electrokinetically driven air flow generating device. According to some embodiments of combining a heat sink and electrokinetically driven air flow electronic device performance (for example, CPU performance) can be significantly improved while simultaneously reducing significantly the system ambient temperature.

In contrast to any previous work in this area where air generation was achieved by providing a set of positive and negative (and/or grounded) probes that are independent of cooling devices (such as heat sinks), in some embodiments, a metallic heat sink itself can be used as the negative/grounded plate.

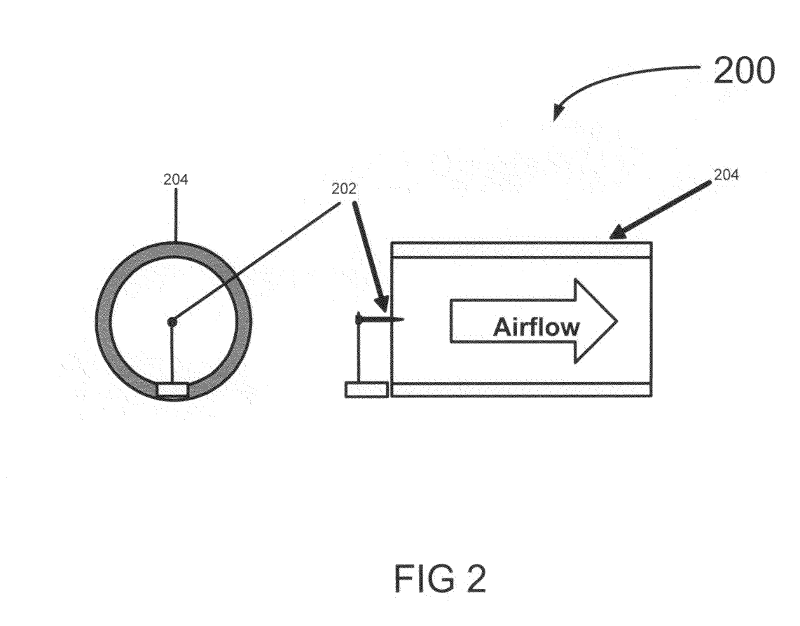

FIG. 2 illustrates a system 200 according to some embodiments. In FIG. 2, system 200 is shown on the left side of FIG. 2 from a front view and on the right side of FIG. 2 from a cross-cut view. In some embodiments, system 200 includes a single point positive probe 202 placed near one end of a simple grounded circular tube 204 (for example, an aluminum grounded tube). In system 200 a substantial amount of airflow can be generated through the tube 204.

In some embodiments, thermal devices (for example, heat sinks) are used as a negative and/or ground probe while positive probes can be made, for example, from metallic wires and/or point probes. Many different embodiments exist using either of these types of probes and using a combination of point and wire probes, and/or using many different types of thermal device (for example, heat sink) geometries. Some embodiments relate to Side-In-Side-Out (SISO) airflow configurations, and some embodiments relate to Top-In-Side-Out (TISO) airflow configurations. Some of these embodiments are illustrated and described herein.

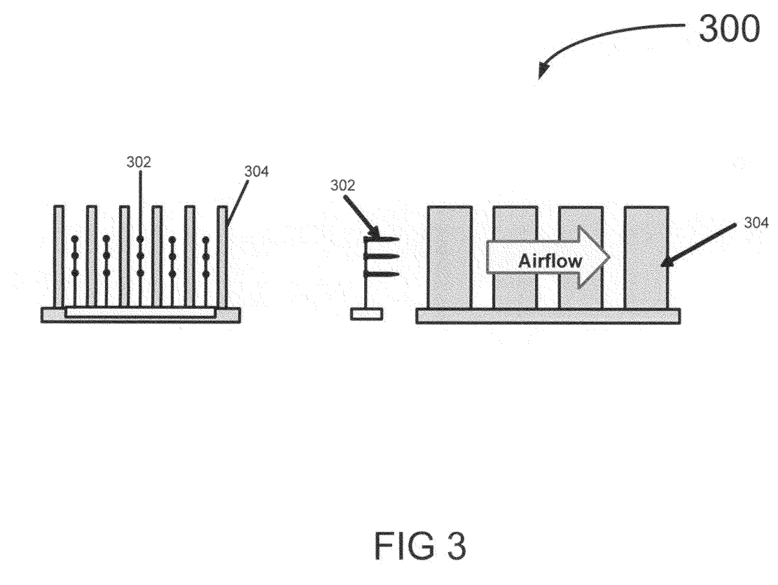

FIG. 3 illustrates a system 300 according to some embodiments. System 300 includes a multi-point positive probe 302 and a grounded heat sink 304 (for example, an aluminum heat sink 304) in a Side-In-Side-Out (SISO) airflow configuration.

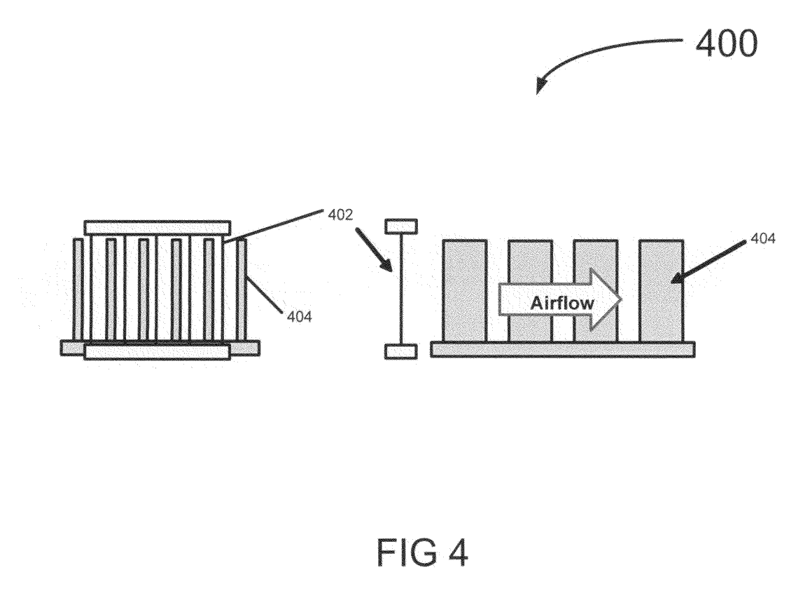

FIG. 4 illustrates a system 400 according to some embodiments. System 400 includes a multi-wire positive probe 402 and a grounded heat sink 404 (for example, an aluminum heat sink 304) in a Side-In-Side-Out (SISO) airflow configuration.

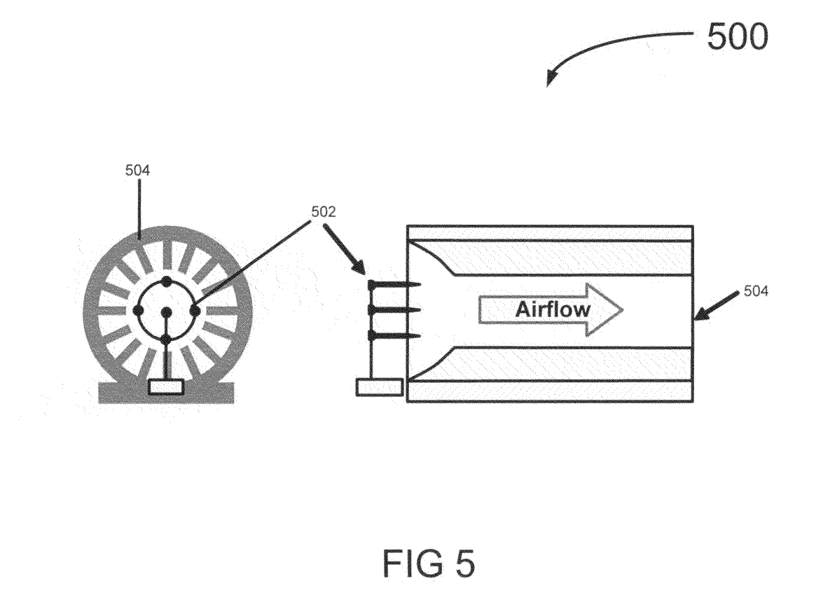

FIG. 5 illustrates a system 500 according to some embodiments. System 500 includes a multi-point positive probe 502 and a grounded tunnel heat sink 504 (for example, an aluminum heat sink 504) in a Side-In-Side-Out airflow (SISO) configuration.

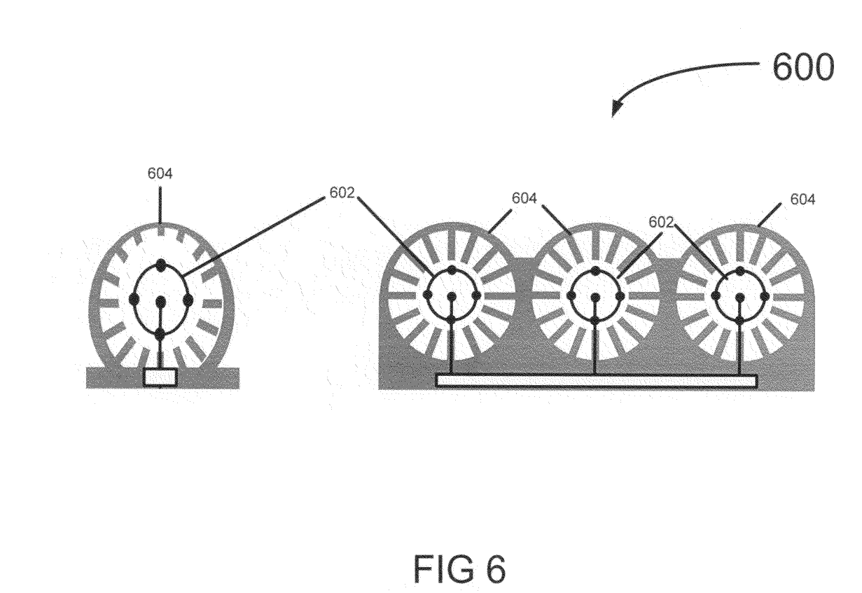

FIG. 6 illustrates a system 600 according to some embodiments. System 600 includes multi-point positive probes 602 and grounded heat sinks 604 (for example, an aluminum heat sink 604) in a front view showing other heat sink geometries in Side-In-Side-Out (SISO) airflow configurations.

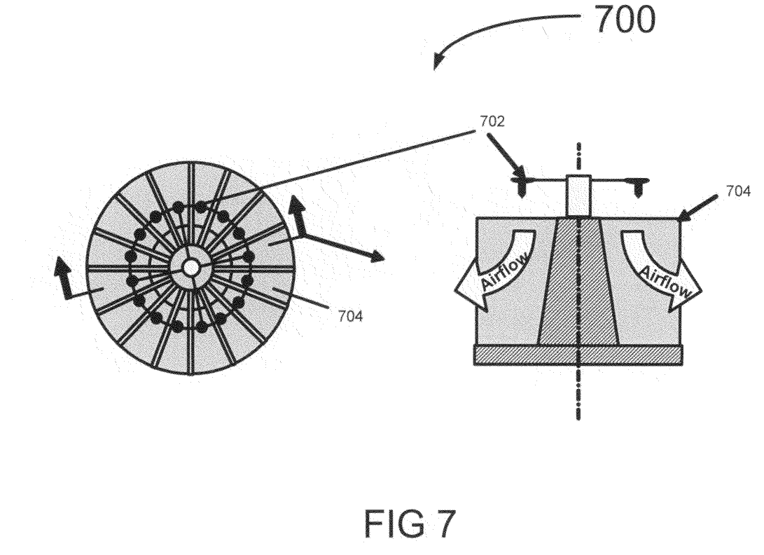

FIG. 7 illustrates a system 700 according to some embodiments. System 700 includes a multi-point positive probe 702 and a grounded radial heat sink 704 (for example, an aluminum heat sink 704) in a Top-In-Side-Out (TISO) airflow configuration.

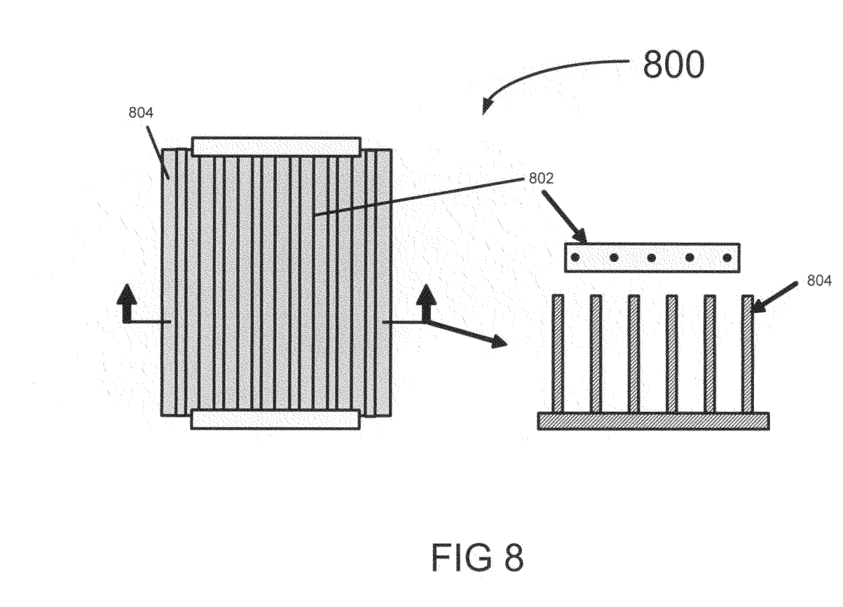

FIG. 8 illustrates a system 800 according to some embodiments. System 800 includes a multi-wire positive probe 802 and a grounded planar heat sink 804 (for example, an aluminum heat sink 804) in a Top-In-Side-Out (TISO) airflow configuration.

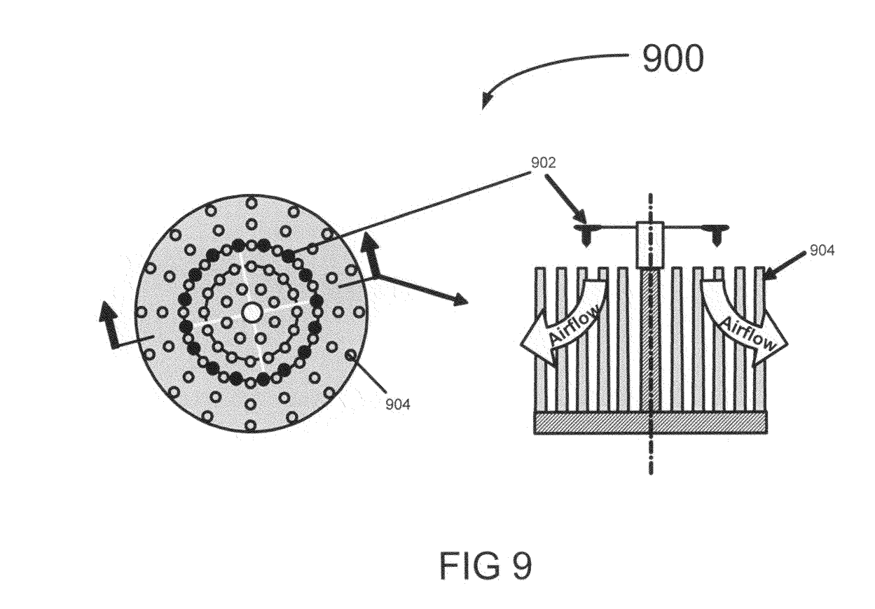

FIG. 9 illustrates a system 900 according to some embodiments. System 900 includes a multi-point positive probe 902 and a grounded pin-fin heat sink 904 (for example, an aluminum heat sink 904) in a Top-In-Side-Out (TISO) airflow configuration.

It is noted that several different examples of probes and heat sinks and airflow configurations are illustrated and described herein for helping to explain embodiments of the invention. However, there are many other embodiments of embedding FANLES technology into a thermal device (such as a heat sink) while using the thermal device as a negative/ground plate. Various modifications exist depending on the particular requirements and applications in a given scenario. Such variations may include a modification to the positive probes for higher performance as well as for better form-factor efficiencies, for example.

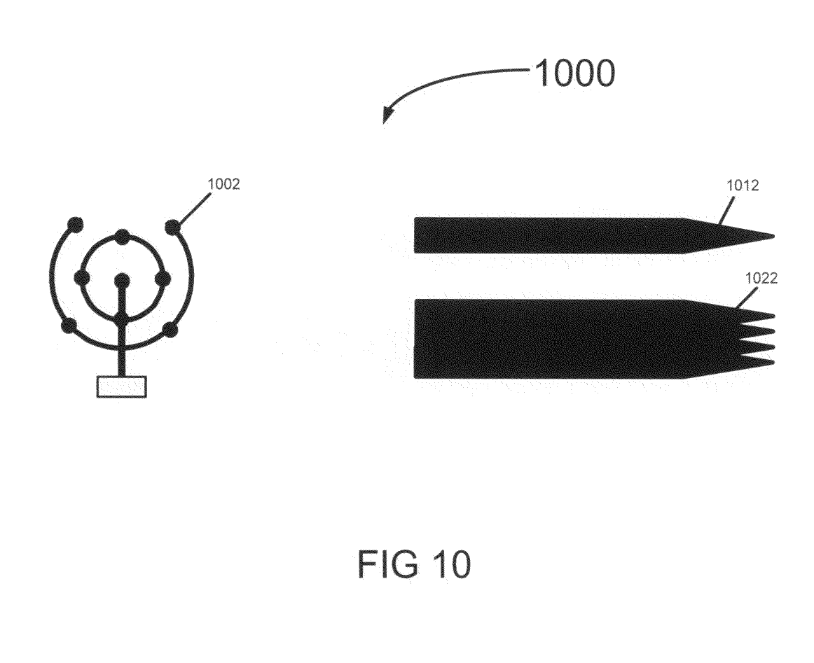

FIG. 10 illustrates a system 1000 according to some embodiments. In some embodiments system 1000 illustrates a multi-ring multi-point positive source 1002 (on left side of FIG. 10), and a positive point probe 1012 with a single discharging point (top right in FIG. 10), as well as a positive point probe 1022 with multi-discharging points (bottom right in FIG. 10).

In some embodiments, hollow aluminum tubes of different diameters and different lengths may be used along with a bare-aluminum heat sink and/or an anodized heat sink. It has been empirically demonstrated that a substantial amount of airflow is generated, and the amount of airflow can be optimized by adjusting the size and length of the tube, the distance between the positive discharge and the heat sink, and the amount of electrical discharge.

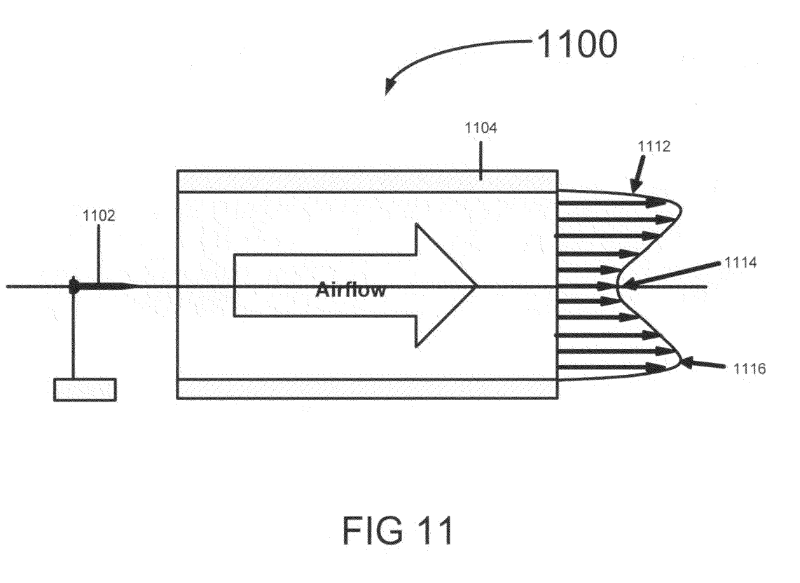

FIG. 11 illustrates a system 1100 according to some embodiments. In some embodiments system 1100 includes a positive source 1102 and an aluminum tube 1104. Airflow velocities 1112 (velocity profile at exit), 1114 (center velocity inside tube 1104) and 1116 (maximum velocity) can be measured. In some embodiments, the center velocity 1114 was measured at approximately 260 lfm (Linear Feet per Minute) and the maximum velocity 1116 was measured at 460-480 lfm. The velocity magnitudes in some embodiments are virtually insensitive to the diameter of the tube 1104, indicating that airflow is essentially driven to the exposed surface of the grounded tube 1104. Contrary to an airflow through a tube driven by an external forced air (i.e. fan driven airflow), in some embodiments, airflow velocity is at its maximum closer to the inside surface of the tube 1104 rather than along the centerline of the tube 1104. This is a great advantage to some embodiments, since a much greater velocity gradient is provided at the surface better convective heat removal capability is present in some embodiments as compared with an externally driven airflow system of an equivalent fluid-dynamic performance. That is, as compared with a fan system that delivers the same volumetric airflow (for example, same cfm—Cubic Feet per Minute), a FANLES system with an embedded heat sink as its negative and/or grounded probe according to some embodiments will provide much better thermal performance via steeper velocity gradient at the surface of the thermal device such as a heat sink tube, for example. Further, contrary to a conventional forced-airflow through a heat sink, a longer heat sink will generate a greater airflow velocity according to some embodiments (as long as the ionized air is not completely depleted before it exits out of the heat sink). In some embodiments, an embedded heat sink with a larger flow cross sectional area (i.e. an aluminum tube with larger diameter) generates a greater amount of total volumetric flow rate as measured in cfm.

In some embodiments, the flow velocity exiting the heat sink through a set of fins/fin-channel centered on a positive emitter is higher while adjacent channels have less (but still significant) airflow velocities. Therefore, in some embodiments, it is not necessary to have a point emitter per every fin-channel. In some embodiments, anodizing a heat sink does not have any impact on airflow velocity (for example, a center fin-channel velocity). In some embodiments, a heat sink is grounded via a mounting hole so the core metal has a path to ground.

In some embodiments, electrokinetic air propulsion is applied to cool electronics using a thermal device such as a heat sink as the ground probe. Previous work in electrokinetic air propulsion for electronics cooling focused on using a separate and independent Electrokinetic module to deliver air flow for the cooling. In contrast, in some embodiments, the separate ground/negative plates are replaced with a metallic heat sink to provide a smaller compact form-factor and a lower cost. In some embodiments, heat sinks of any integrated circuit such as a CPU and/or a chipset may be used. This is particularly compelling when used in applications where a low acoustic signature with high reliability is desirable, such as in typical consumer electronics devices such as set top boxes and digital TVs.

Although some embodiments have been described herein as being implemented using heat sinks, according to some embodiments these particular implementations may not be required and other thermal devices other than heat sinks may be used.

Although some embodiments have been described in reference to particular implementations, other implementations are possible according to some embodiments. Additionally, the arrangement and/or order of circuit elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other.

An algorithm is here, and generally, considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers or the like. It should be understood, however, that all of these and similar terms are to be associated with the appropriate physical quantities and are merely convenient labels applied to these quantities.

Some embodiments may be implemented in one or a combination of hardware, firmware, and software. Some embodiments may also be implemented as instructions stored on a machine-readable medium, which may be read and executed by a computing platform to perform the operations described herein. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other form of propagated signals (e.g., carrier waves, infrared signals, digital signals, the interfaces that transmit and/or receive signals, etc.), and others.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

Although flow diagrams and/or state diagrams may have been used herein to describe embodiments, the inventions are not limited to those diagrams or to corresponding descriptions herein. For example, flow need not move through each illustrated box or state or in exactly the same order as illustrated and described herein.

The inventions are not restricted to the particular details listed herein. Indeed, those skilled in the art having the benefit of this disclosure will appreciate that many other variations from the foregoing description and drawings may be made within the scope of the present inventions. Accordingly, it is the following claims including any amendments thereto that define the scope of the inventions.

1-21. (canceled)

22. An apparatus comprising:
a thermal device to cool an electronic device; and
a charged electrode to ionize air molecules to create an air flow near the thermal device, wherein some of the air flow moves over the thermal device and some of the air flow passes through the thermal device.

23. The apparatus of claim 22, wherein the charged electrode and a second electrode provide an electrostatic field to ionize the air molecules and provide the air flow.

24. The apparatus of claim 22, wherein the thermal device is a heat sink.

25. The apparatus of claim 22, wherein the charged source is a single point probe.

26. The apparatus of claim 22, wherein the charged source is a multi-point probe.

27. The apparatus of claim 22, wherein the charged source is a wire probe.

28. The apparatus of claim 22, wherein the air flow flows relative to the thermal device in a Side-In-Side-Out manner.

29. The apparatus of claim 22, wherein the air flow flows relative to the thermal device in a Top-In-Side-Out manner.

30. The apparatus of claim 22, wherein the air flow is produced without any noise or mechanically moving parts.

31. The apparatus of claim 22, wherein the air flow is produced using an electrostatic field in which the charged source and at least the portion of the thermal device are situated.

32. A method comprising:
ionizing air molecules using a charged electrode to create an air flow near a thermal device used to cool an electronic device, wherein some of the air flow moves over the thermal device and some of the air flow passes through the thermal device.

33. The method of claim 32, further comprising providing an electrostatic field to ionize the air molecules and provide the air flow using the charged electrode and a second electrode.

34. The method of claim 32, wherein the thermal device is a heat sink.

35. The method of claim 32, wherein the charged source is a single point probe.

36. The method of claim 32, wherein the charged source is a multi-point probe.

37. The method of claim 32, wherein the charged source is a wire probe.

38. The method of claim 32, wherein the air flow flows relative to the thermal device in a Side-In-Side-Out manner.

39. The method of claim 32, wherein the air flow flows relative to the thermal device in a Top-In-Side-Out manner.

40. The method of claim 32, further comprising producing the air flow without any noise or mechanically moving parts.

41. The method of claim 32, further comprising producing the the air flow using an electrostatic field in which the charged source and at least the portion of the thermal device are situated.

42. The method of claim 32, wherein the electrokinetically driven airflow moves over the thermal device.
